(19) United States
(12) Patent Application Publication
(10) Pub. No.: US 2013/0058062 A1
(43) Pub. Date: Mar. 7, 2013

(54) METHOD FOR MANUFACTURING BASE MATERIAL HAVING GOLD-PLATED METAL FINE PATTERN, BASE MATERIAL HAVING GOLD-PLATED METAL FINE PATTERN, PRINTED WIRING BOARD, INTERPOSER, AND SEMICONDUCTOR DEVICE

(71) Applicants: Kenya Tachibana, Fujieda-shi (JP); Teppei Ito, Utsunomiya-shi (JP); Yasuaki Mitsui, Fujieda-shi (JP)

(72) Inventors: Kenya Tachibana, Fujieda-shi (JP); Teppei Ito, Utsunomiya-shi (JP); Yasuaki Mitsui, Fujieda-shi (JP)

(73) Assignee: SUMITOMO BAKELITE CO., LTD., Tokyo (JP)

(21) Appl. No.: 13/697,720

(22) PCT Filed: May 26, 2011
(86) PCT No.: PCT/JP2011/062096

§ 371 Date: Nov. 13, 2012

(30) Foreign Application Priority Data
May 26, 2010 (JP) 2010-120399

(51) Int. Cl. H05K 3/10; H05K 7/06; H05K 1/09

(52) U.S. Cl. 361/783; 216/13; 174/257

(57) ABSTRACT

A method for manufacturing a base material having a gold-plated metal fine pattern is disclosed, comprising the steps of preparing a base material having a supporting surface made of a resin; forming a primer resin layer having surface roughness of 0.5 μm or less on the supporting surface, and forming a metal fine pattern thereon by an SAP process to obtain a base material having a metal fine pattern; and applying a gold-plating treatment to at least one part of a surface of the metal fine pattern; wherein the base material having a metal fine pattern is subjected to a palladium removal treatment in an optional stage before carrying out the gold-plating treatment.

### TECHNICAL FIELD

The present invention relates to a method for manufacturing a base material having a gold-plated metal fine pattern, a base material having a gold-plated metal fine pattern manufactured using the method, a printed wiring board, particularly a motherboard, an interposer or the like, and a semiconductor device using the printed wiring board.

### BACKGROUND ART

In recent years, with growing demands of higher function, light-weight design, miniaturization, and thinning of electronic devices, high-density integration and high-density packaging of electronic components have been developed. Circuit wiring of printed wiring boards used for these electronic devices tends to be highly densified and complicated, thus circuit patterns have been developed with miniaturization.

In particular, miniaturization of circuit patterns is required on a surface of a printed wiring board, called an interposer, on which a semiconductor element is mounted.

A motherboard and an interposer are known as a printed wiring board of a semiconductor device. The interposer is a printed wiring board similar to the motherboard, and exists between a semiconductor element (bare chip) or a semiconductor package and a motherboard, and is mounted on the motherboard.

The interposer may also be used as a substrate on which a semiconductor package is mounted, similar to the motherboard, and is used as a package substrate or a module substrate, as an unusual usage which is different from that of the motherboard.

The package substrate means that the interposer is used as a substrate of a semiconductor package. The semiconductor package includes a type in which a semiconductor element is mounted on a lead frame and then both of them are connected by wire bonding and sealed with a resin; and a type in which an interposer is used as a package substrate and a semiconductor element is mounted on the interposer, and then both of them are connected by a method such as wire bonding and sealed with a resin.

When the interposer is used as the package substrate, it is possible to dispose a connection terminal to a motherboard on a plane on the side for connecting the motherboard of a semiconductor package (lower surface side of the interposer). It is also possible to stepwisely increase the wiring dimension from the side for connecting a semiconductor element of the interposer to the side for connecting a motherboard, thus filling a wiring dimension gap between the semiconductor element and the motherboard.

To cope with further progress in miniaturization of a circuit, an interposer of a multi-layer printed wiring board is also used.

A distance of a conductor circuit width and a distance between circuits refer to line-and-space (L/S). At present, line-and-space (L/S) of a semiconductor element internal circuit has reached a submicron level, and line-and-space (L/S) of a connection terminal of an outermost layer circuit on the side for connecting a semiconductor element of an interposer to be connected thereto is about several tens of μm/several tens of μm. In contrast, line-and-space (L/S) of a connection terminal of an outermost layer circuit on the side for connecting a motherboard of an interposer is about several hundreds of μm/several hundreds of μm, whereas, line-and-space (L/S) of a connection terminal of an outermost layer circuit on the side for connecting an interposer of a motherboard is also about several hundreds of μm/several hundreds of μm.

The module substrate means that it is used as a substrate on which a plurality of semiconductor packages or a semiconductor element before packaging is mounted in a single module. Miniaturization of a circuit is also required of a surface, on which a semiconductor element is mounted, of a module substrate.

In recent years, a semi-additive method (SAP) has begun to be carried out as a technology for formation of a fine circuit of a printed wiring board. SAP is a method in which a roughening treatment is applied to a surface of a core substrate or an interlayer insulating layer and an electroless plating treatment for forming a backing is subsequently applied to form an electroplating mask using a resist, and thick copper plating of a circuit forming portion is carried out by electroplating, and then a circuit is formed on the insulating layer by removal of the resist and soft etching. Roughening refers to formation of fine irregularities on a conductor circuit surface.

Gold-plating is carried out as a final surface treatment of a package portion, a terminal portion and the like of a circuit on a printed wiring board.

One of typical methods of gold-plating includes an electroless nickel-gold-plating method. An electroless nickel immersion gold (ENIG) method is one of electroless nickel-gold-plating methods, and is a method in which an immersion gold is carried out in an electroless gold-plating treatment stage.

In the electroless nickel-gold-plating method, it is possible to carry out prevention of diffusion of conductor material and improvement in corrosion resistance and prevention of oxidation of nickel in the circuit and the terminal portion.

Application of an electroless nickel-palladium-gold-plating method has begun to be considered as a method for other gold-plating. In this method, a pretreatment is carried out by an appropriate method such as a cleaner treatment for the purpose of plating, and then a palladium catalyst is applied and, furthermore, an electroless nickel-plating treatment, an electroless palladium-plating treatment and an electroless gold-plating treatment are sequentially carried out.

An electroless nickel/electroless palladium/immersion gold-plating (ENEPIG) method is a method in which an immersion gold is carried out in an electroless gold-plating treatment stage of an electroless nickel-palladium-gold-plating method (Patent Literature 1).

In the electroless nickel-palladium-gold-plating method, it is possible to carry out prevention of diffusion of a conductor material and improvement in corrosion resistance, prevention of oxidation of nickel and prevention of diffusion in the circuit and the terminal portion. In the electroless nickel-palladium-gold-plating method, it is possible to prevent oxidation of nickel due to gold by providing an electroless palladium-plated film, thus improving reliability of lead-free solder bonding with high heat load. Furthermore, since diffusion of nickel does not occur without increasing a film thickness of gold, it is possible to reduce costs as compared with an electroless nickel-gold-plating method.

However, after forming a circuit of a printed wiring board by an SAP process, when electroless metal-plating by an electroless nickel-gold-plating treatment or an electroless nickel-palladium-gold-plating treatment is applied to the circuit, abnormal precipitation of metal occurs on an insulating film supporting a conductor circuit, or occurs in the vicinity of a circuit of a resin surface of a substrate, thus causing deterioration in quality of a plated surface.

In particular, when a circuit is miniaturized so as to respond to densification and complication of circuit wiring in recent years, a short circuit is likely to generate due to metal precipitated between adjacent wirings or between terminals. In particular, a connection terminal of an outermost layer circuit on the side for connecting a semiconductor element of an interposer for package substrate is likely to cause a short circuit because of narrow line-and-space (L/S) of about several tens of μm/several tens of μm.

Patent Literature 2 discloses a method in which a circuit pattern is formed by etching after carrying out electroless copper plating and electrolytic copper plating, and electroless metal-plating is carried out in the circuit, characterized in that a solution containing nitric acid, chlorine ions and a cationic polymer is used, as a liquid for removing a metal precipitated catalyst adhered to a resin surface, between the etching step and the electroless metal-plating step.

Patent Literature 2 also discloses a method in which a known bridge prevention liquid is allowed to act between the etching step and the electroless metal-plating step, in addition to the removal liquid, so as to carry out electroless metal-plating while maintaining insulating properties with respect to those with narrower space between wirings.

However, even if a method using a specific removal liquid method and a method using the specific removal liquid in combination with a known bridge prevention liquid disclosed in Patent Literature 2 are used, it may be impossible to sufficiently prevent abnormal precipitation of metal in the vicinity of a circuit in a case electroless metal-plating due to an electroless nickel-gold-plating treatment or an electroless nickel-palladium-gold-plating treatment is applied on a surface of a circuit formed by an SAP method.

According to the study of the present inventors, it is considered that the above-mentioned abnormal precipitation is caused by a palladium catalyst which is applied in the process of an SAP method, and a palladium catalyst which is applied in the process of an electroless nickel-gold-plating treatment or an electroless nickel-palladium-gold-plating treatment.

In the SAP process, an electroless plating catalyst is applied before carrying out electroless plating so as to improve electroless plating adhesion properties of a resin surface. Electroless plating adhesion properties refer to ease of adsorption of electroless plated metal to a catalyst. A palladium catalyst is often used as an electroless plating catalyst.

Since a resin surface where the SAP method is carried out is formed of a resin which exhibits satisfactory adhesion of a palladium catalyst, a palladium metal residue may remain on a resin surface on which a circuit is formed only by carrying out soft etching after electroplating.

In the process of an electroless nickel-gold-plating treatment or an electroless nickel-palladium-gold-plating treatment, a palladium catalyst is imparted before carrying out nickel electroless plating so as to improve electroless plating adhesion properties of a circuit surface. However, as mentioned above, the resin surface with a circuit formed thereon is formed of the resin which exhibits satisfactory adhesion to a palladium catalyst so as to improve processability in the SAP process. Therefore, the palladium catalyst imparted on this stage adheres to not only a circuit surface to be plated, but also a resin surface in the vicinity of a circuit.

It is considered that abnormal precipitation may occur on a resin surface in the vicinity of a circuit since a palladium catalyst or palladium metal residue existing on the resin surface acts as nuclei.

The present inventors have found that a large amount of abnormal precipitation is likely to occur as compared with the case of carrying out an electroless nickel-gold-plating treatment when SAP is used in combination with an electroless nickel-palladium-gold-plating treatment. Therefore, when an electroless nickel-palladium-gold-plating treatment is carried out, it is highly required to prevent abnormal precipitation, particularly.

### CITATION LIST

### Patent Literature

### Patent Literature 1

Japanese Unexamined Patent Application, First Publication No. 2008-144188

### Patent Literature 2

Japanese Unexamined Patent Application, First Publication No. 2005-213547

### SUMMARY OF INVENTION

### Technical Problem

The present invention has been completed in view of the above circumstances, and an object of the present invention is to provide a method for manufacturing a base material having a gold-plated metal fine pattern, which is excellent in electroless plating adhesion properties in an SAP process and enables formation of a fine circuit, and also suppresses abnormal precipitation in an electroless nickel-palladium-gold-plating treatment or an electroless nickel-gold-plating treatment, thus enabling an improvement in inter-wiring insulation reliability and connection reliability of a fine circuit.

Another object thereof is to provide a base material having a gold-plated metal fine pattern obtained by the above manufacturing method, a printed wiring board, particularly an interposer, a motherboard or the like, which is obtained using the gold-plated metal fine pattern as a conductor circuit, and a semiconductor device obtained using the printed wiring board.

### Solution to Problem

The above objects are achieved by inventions (1) to (15) shown below.

(1) A method for manufacturing a base material having a gold-plated metal fine pattern, including the steps of:

preparing a base material having a supporting surface made of a resin;

forming a metal fine pattern on the supporting surface made of a resin of the base material by a semi-additive method to obtain a base material having a metal fine pattern; and

applying a gold-plating treatment selected from the group consisting of an electroless nickel-palladium-gold-plating treatment and an electroless nickel-gold-plating treatment to at least one part of a surface of the metal fine pattern; wherein

a primer resin layer having surface roughness represented by the arithmetic average of 0.5 μm or less is formed on the supporting surface made of a resin;

a metal fine pattern is formed on the primer resin layer by a semi-additive method including an electroless metal-plating treatment using a palladium catalyst;

the base material having a metal fine pattern is subjected to at least one palladium removal treatment selected from the group consisting of (a) to (d) shown below, in an optional stage before carrying out the gold-plating treatment after formation of the metal fine pattern:

(a) a treatment with a palladium removal agent,
(b) a treatment with a potassium cyanide (KCN)-containing liquid,
(c) a desmear treatment with a chemical liquid, and
(d) a dry desmear treatment with plasma; and

the palladium removal treatment is carried out, and then the gold-plating treatment is carried out.

(2) The method for manufacturing a base material having a gold-plated metal fine pattern according to the above (1), wherein a palladium catalyst is applied on a surface of a metal fine pattern of a base material having a metal fine pattern in a gold-plating treatment step after carrying out the palladium removal treatment, and then the base material having a metal fine pattern is subjected to at least one second palladium removal treatment selected from the group consisting of (e) and (f) shown below:
(e) a treatment with a solution at pH 10 to 14, and
(f) a dry desmear treatment with plasma, in an optional stage before an electroless nickel-plating treatment or an electroless palladium-plating treatment is carried out.
(3) The method for manufacturing a base material having a gold-plated metal fine pattern according to the above (1) or (2), wherein the base material having a metal fine pattern is a printed wiring board, and the metal fine pattern is a conductor circuit on a surface of a printed wiring board.
(4) The method for manufacturing a base material having a gold-plated metal fine pattern according to the above (3), wherein the printed wiring board is a motherboard, and line-and-space (L/S) of a conductor circuit at a plating portion is 300 to 500 μm/300 to 500 μm.
(5) The method for manufacturing a base material having a gold-plated metal fine pattern according to the above (3), wherein the printed wiring board is an interposer.
(6) The method for manufacturing a base material having a gold-plated metal fine pattern according to the above (5), wherein line-and-space (L/S) of a conductor circuit at a plating portion on the side for connecting a semiconductor element of the interposer is 10 to 50 μm/10 to 50 μm.
(7) The method for manufacturing a base material having a gold-plated metal fine pattern according to the above (5), wherein line-and-space (L/S) of a conductor circuit at a plating portion on the side for connecting a motherboard of the interposer is 300 to 500 μm/300 to 500 μm.
(8) A base material having a gold-plated metal fine pattern, which is manufactured by the method according to the above (1).
(9) A printed wiring board in which a composite gold-plated layer selected from the group consisting of a nickel-palladium-gold-plated layer and a nickel-gold-plated layer is formed on a conductor circuit of the printed wiring board surface by the method according to the above (1).
(10) The printed wiring board according to the above (9), wherein line-and-space (L/S) of a portion including the composite gold-plated layer of the conductor circuit is 300 to 500 μm/300 to 500 μm.
(11) An interposer in which a composite gold-plated layer selected from the group consisting of a nickel-palladium-gold-plated layer and a nickel-gold-plated layer is formed on a conductor circuit of the interposer surface by the method according to the above (1).
(12) The interposer according to the above (11), wherein line-and-space (L/S) of a conductor circuit at a plating portion on the side for connecting a semiconductor element of the interposer is 10 to 50 μm/10 to 50 μm.
(13) The interposer according to the above (11), wherein line-and-space (L/S) of a conductor circuit at a plating portion on the side for connecting a motherboard of the interposer is 300 to 500 μm/300 to 500 μm.
(14) A semiconductor device in which a semiconductor is mounted on the printed wiring board according to the above (9) or (10).
(15) A semiconductor device in which a semiconductor is mounted on an interposer of a printed wiring board including the interposer according to any one of the above (11) to (13).

### Advantageous Effects of Invention

In the method for manufacturing a base material having a gold-plated metal fine pattern of the present invention, a series of the steps (palladium catalyst-imparting, electroless metal-plating and electrolytic metal-plating) of a SAP method are carried out after providing a primer resin layer having surface roughness represented by the arithmetic average of 0.5 μm or less between an insulating layer and a conductor circuit layer. Therefore, an electroless metal-plating layer is formed on a resin surface which exhibits satisfactory adhesion to a palladium catalyst and also has uniform and dense irregularities. Accordingly, a surface of a base material made of a resin is excellent in electroless plating adhesion properties, and a metal fine pattern having excellent peel strength is formed. The surface roughness refers, for example, to a numerical value to be measured in accordance with JIS B 0601, and the peel strength refers to a peel strength of an interface between a resin and metal, which is measured in accordance with JIS C 6481. The surface roughness represented by the arithmetic average can be measured, for example, in accordance with JIS B 0601.

Furthermore, it is possible to prevent abnormal precipitation of palladium metal during formation of a metal fine pattern by SAP and a gold-plating treatment by an electroless nickel-palladium-gold-plating treatment or an electroless nickel-gold-plating treatment by carrying out at least one palladium removal treatment selected from the group consisting of the above-mentioned (a) to (d).

It is possible to suppress abnormal precipitation of metal during a gold-plating treatment to a lower level by carrying out a second palladium removal treatment of (e) or (f) until electroless palladium plating is carried out after imparting a palladium catalyst in the case of an electroless nickel-palladium-gold-plating treatment, or carrying out the second palladium removal treatment until electroless nickel plating is carried out after imparting a palladium catalyst in the case of an electroless nickel-gold-plating treatment.

Accordingly, it is possible to obtain a base material having a gold-plated metal fine pattern having a fine circuit excellent in inter-wiring insulation reliability and connection reliability, particularly a printed wiring board such as an interposer or a motherboard, by carrying out a method for manufacturing a base material having a gold-plated metal fine pattern of the present invention. A conductor circuit of an outermost layer on the side for connecting a motherboard of an interposer, and a conductor circuit of an outermost layer on the side for connecting an interposer of a motherboard are formed by a method of the present invention, in the same manner as mentioned above, and then only a terminal portion is exposed and other portions are covered with a solder resist layer, and a gold-plating treatment can be carried out to the terminal portion by the method of the present invention.

### BRIEF DESCRIPTION OF DRAWINGS

FIG. 1A is a schematic view showing an example (one step of the first half) of a method for manufacturing a base material having a gold-plated metal fine pattern of the present invention.

FIG. 1B is a schematic view showing an example (one step of the first half) of a method for manufacturing a base material having a gold-plated metal fine pattern of the present invention.

FIG. 1C is a schematic view showing an example (one step of the first half) of a method for manufacturing a base material having a gold-plated metal fine pattern of the present invention.

FIG. 1D is a schematic view showing an example (one step of the first half) of a method for manufacturing a base material having a gold-plated metal fine pattern of the present invention.

FIG. 1E is a schematic view showing an example (one step of the first half) of a method for manufacturing a base material having a gold-plated metal fine pattern of the present invention.

FIG. 1F is a schematic view showing an example (one step of the first half) of a method for manufacturing a base material having a gold-plated metal fine pattern of the present invention.

FIG. 1G is a schematic view showing an example (one step of the latter half) of a method for manufacturing a base material having a gold-plated metal fine pattern of the present invention.

FIG. 1H is a schematic view showing an example (one step of the latter half) of a method for manufacturing a base material having a gold-plated metal fine pattern of the present invention.

FIG. 1I is a schematic view showing an example (one step of the latter half) of a method for manufacturing a base material having a gold-plated metal fine pattern of the present invention.

FIG. 1J is a schematic view showing an example (one step of the latter half) of a method for manufacturing a base material having a gold-plated metal fine pattern of the present invention.

FIG. 2A is a schematic view describing a method for roughening a primer resin layer.

FIG. 2B is a schematic view describing a method for roughening a primer resin layer.

FIG. 2C is a schematic view describing a method for roughening a primer resin layer.

FIG. 3 is a block diagram showing a procedure for an ENEPIG method.

FIG. 4 is a block diagram showing a procedure for an ENIG method.

FIG. 5 is a view schematically showing an example of amounted layered structure of a semiconductor device according to an embodiment of the present invention.

FIG. 6 is a view schematically showing an example of a semiconductor package using an interposer according to an embodiment of the present invention.

FIG. 7 is a view schematically showing a comb tooth pattern-shaped copper circuit formed on a test piece of Example.

FIG. 8 is an electron micrograph of a terminal portion of a plated material obtained in Example 1.

FIG. 9 is an electron micrograph of a terminal portion of a plated material obtained in Example 2.

FIG. 10 is an electron micrograph of a terminal portion of a plated material obtained in Example 3.

FIG. 11 is an electron micrograph of a terminal portion of a plated material obtained in Example 4.

FIG. 12 is an electron micrograph of a terminal portion of a plated material obtained in Example 5.

FIG. 13 is an electron micrograph of a terminal portion of a plated material obtained in Example 12.

FIG. 14 is an electron micrograph of a terminal portion of a plated material obtained in Comparative Example 1.

### DESCRIPTION OF EMBODIMENTS

The method for manufacturing a base material having a gold-plated metal fine pattern of the present invention includes the steps of:

preparing a base material having a supporting surface made of a resin;

forming a metal fine pattern on the supporting surface made of a resin of the base material by a semi-additive method to obtain a base material having a metal fine pattern; and

applying a gold-plating treatment selected from the group consisting of an electroless nickel-palladium-gold-plating treatment and an electroless nickel-gold-plating treatment to at least one part of a surface of the metal fine pattern; wherein

a primer resin layer having surface roughness represented by the arithmetic average of 0.5 μm or less is formed on the supporting surface made of a resin;

a metal fine pattern is formed on the primer resin layer by a semi-additive method including an electroless metal-plating treatment using a palladium catalyst;

the base material having a metal fine pattern is subjected to at least one palladium removal treatment selected from the group consisting of:

(a) a treatment with a palladium removal agent,
(b) a treatment with a potassium cyanide (KCN)-containing liquid,
(c) a desmear treatment with a chemical liquid, and
(d) a dry desmear treatment with plasma, in an optional stage before carrying out the gold-plating treatment after formation of the metal fine pattern; and

the palladium removal treatment is carried out, and then the gold-plating treatment is carried out.

In the method for manufacturing a base material having a gold-plated metal fine pattern of the present invention, it is preferred that a palladium catalyst be applied on a surface of metal fine pattern of a base material having a metal fine pattern in a gold-plating treatment step after carrying out the palladium removal treatment, and then the base material having a metal fine pattern be subjected to at least one second palladium removal treatment selected from the group consisting of:

(e) a treatment with a solution at pH 10 to 14, and
(f) a dry desmear treatment with plasma, in an optional stage before an electroless nickel-plating treatment or an electroless palladium-plating treatment is carried out.

The method for manufacturing a base material having a gold-plated metal fine pattern of the present invention will be described below by way of the case where a copper circuit is formed on a core base material by SAP and a gold-plating treatment is applied to a surface of the copper circuit, as an example.

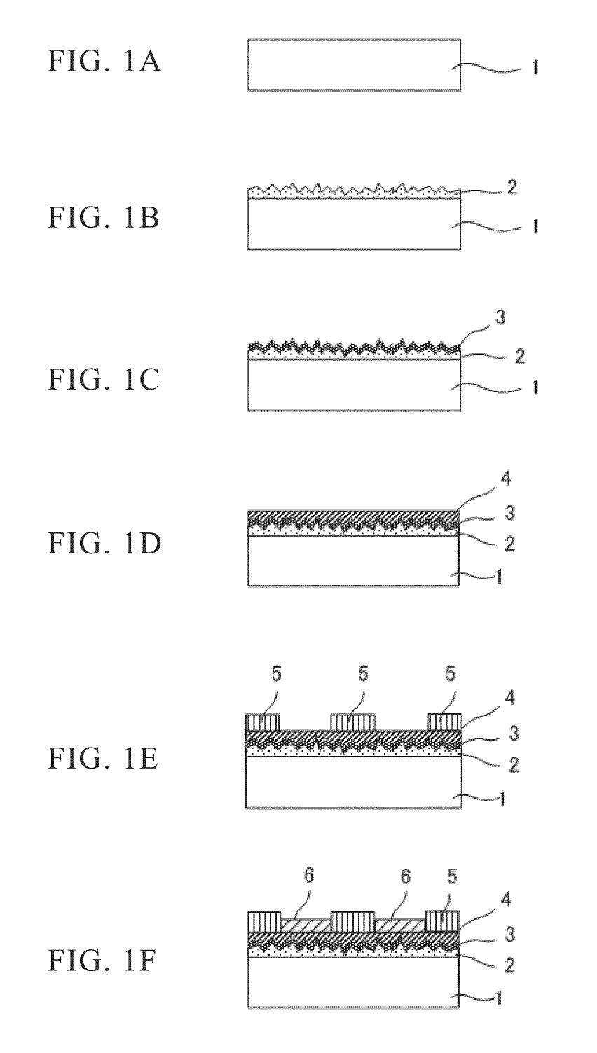

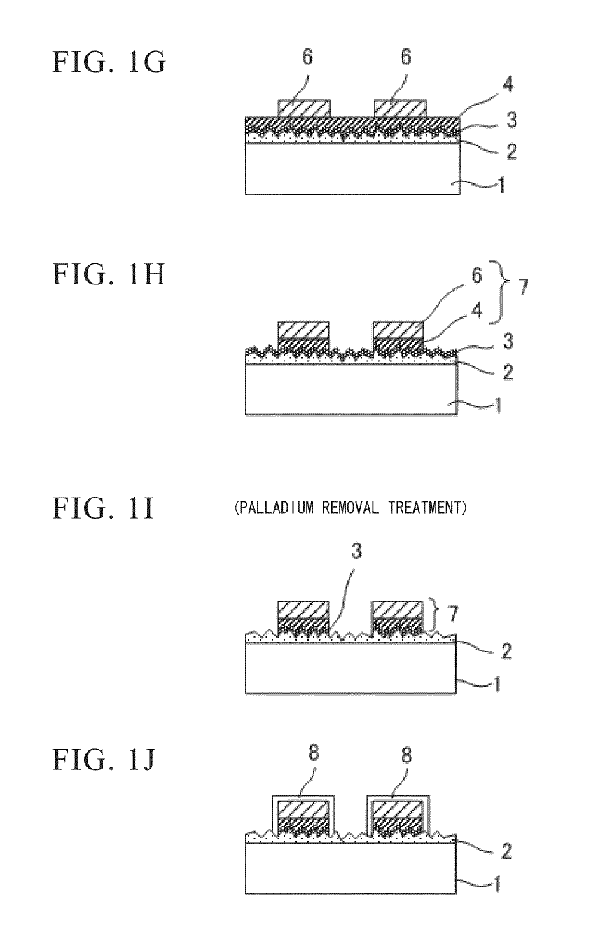

FIG. 1A to FIG. 1J are views each describing a procedure for a manufacturing method.

In this example, first, a core base material 1 of a printed wiring board is prepared as a base material having a supporting surface made of a resin in the procedure shown in FIG. 1A.

In the present invention, “base material having a supporting surface made of a resin” is an object to be subjected to SAP and a gold-plating treatment by the method of the present invention, and a surface of a base material may be made of a resin and the deep portion of a base material may also be made of a material other than the resin.

In the case of manufacturing a printed wiring board, a core base material may be used, or a laminate may be used in which multi-layer wiring is formed on a core base material, and an interlayer insulating layer is laminated on an outermost surface.

It is possible to use, as the core base material, for example, known core substrates such as a copper clad epoxy laminate based on glass fablics, and known prepregs.

The laminate in which multi-layer wiring is formed can be obtained by repeatedly forming a conductor circuit layer on a core base material by means of an SAP method using a conventionally known method.

Next, a primer resin layer 2 is formed on a core base material 1 so as to improve electroless plating adhesion properties in the procedure shown in FIG. 1B. The primer resin preferably contains a resin selected from the group consisting of a polyamide resin and a polyimide resin. These resins have satisfactory adhesion of a palladium catalyst, and electroless plating adhesion properties.

The polyamide resin is not particularly limited, and is preferably represented by the structural formula (1) shown below:

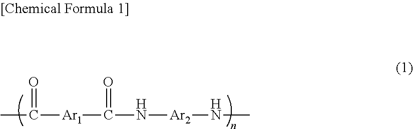

wherein Ar₁ and Ar₂ represent a divalent hydrocarbon group or an aromatic group, or may be different in repetitions; and n represents a repeating unit and is an integer of 5 to 5,000.

Among these polyamide resins, a rubber-modified polyamide resin is preferred since flexibility is improved, thus enabling an improvement in adhesion with a conductor layer. Rubber modification refers to inclusion of a skeleton of a rubber component, such as a butadiene or acrylonitrile group on Ar₁ and/or Ar₂ of the structural formula (1). More preferably, it refers to inclusion of a phenolic hydroxyl group on Ar₁ and/or Ar₂ since excellent compatibility with an epoxy resin is achieved, and also heat-curing enables three-dimensional crosslinking with a polyamide polymer, resulting in excellent mechanical strength. Specific examples of more preferred polyamide resin include those represented by the structural formula (2) shown below:

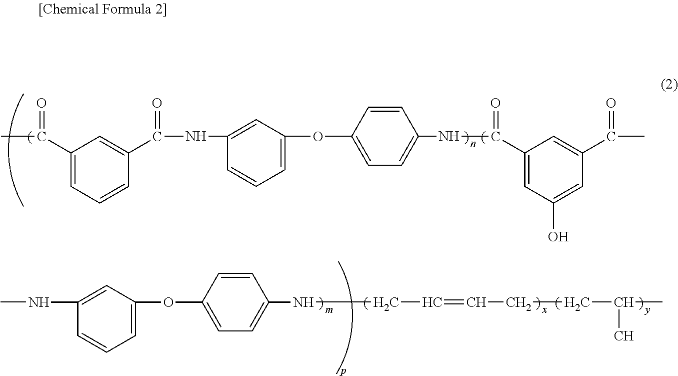

wherein n and m represent the number of mols charged, n/(m+n)=0.05 to 2 (charging molar ratio), and x, y and p represent a weight ratio and (x+y)/p=0.2 to 2 (weight ratio). The weight average molecular weight is within a range from 8,000 to 100,000, and the equivalent of a hydroxyl group is within a range from 1,000 to 5,000 g/eq.

Examples of the polyimide resin include, but are not limited to, those obtained by dehydration condensation of a known tetracarboxylic dianhydride and diamine as raw materials; and those having an imide skeleton obtained from tetracarboxylic dianhydride and diisocyanate as raw materials, represented by the structural formula (3) shown below:

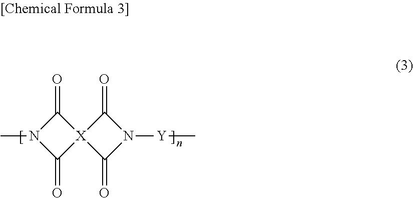

wherein X represents a skeleton derived from a tetracarboxylic acid dihydrate, and Y represents a skeleton derived from diamine or diisocyanate.

Among these polyimide resins, a silicone-modified polyimide represented by the structural formula (4) shown below is preferred since the primer resin becomes soluble in a solvent, thus enabling formation into a varnish. Conversion into a varnish refers to dissolution of a solid resin component in a dilution solvent until an insoluble component disappears:

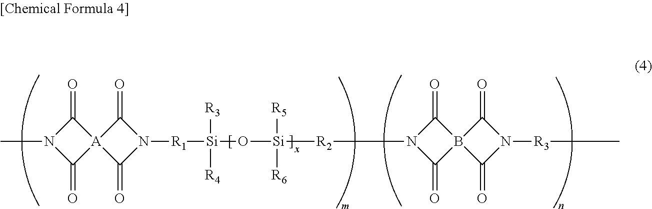

wherein R₁ and R₂ represent a divalent aliphatic group or aromatic group of 1 to 4 carbon atoms, R₃, R₄, R₅, and R₆ represent a monovalent aliphatic group or aromatic group, A and B represent a trivalent or tetravalent aliphatic group or aromatic group, R₇ represents a divalent aliphatic group or aromatic group, and k, m and n represent the number of repeating units and are integers of 5 to 5,000.

A polyamideimide resin having an amide skeleton in a polyimide block is also preferred since the primer resin becomes soluble in a solvent, thus enabling conversion into a varnish.

Surface roughness represented by the arithmetic average of the primer resin layer is preferably from 0.01 to 0.5 μm, and particularly preferably from 0.05 to 0.2 μm. When the surface roughness is within the above range, the surface of the primer resin layer has uniform and dense irregularities and is excellent in electroless plating adhesion properties and peel strength. The surface roughness represented by the arithmetic average can be measured, for example, in accordance with JIS B 0601.

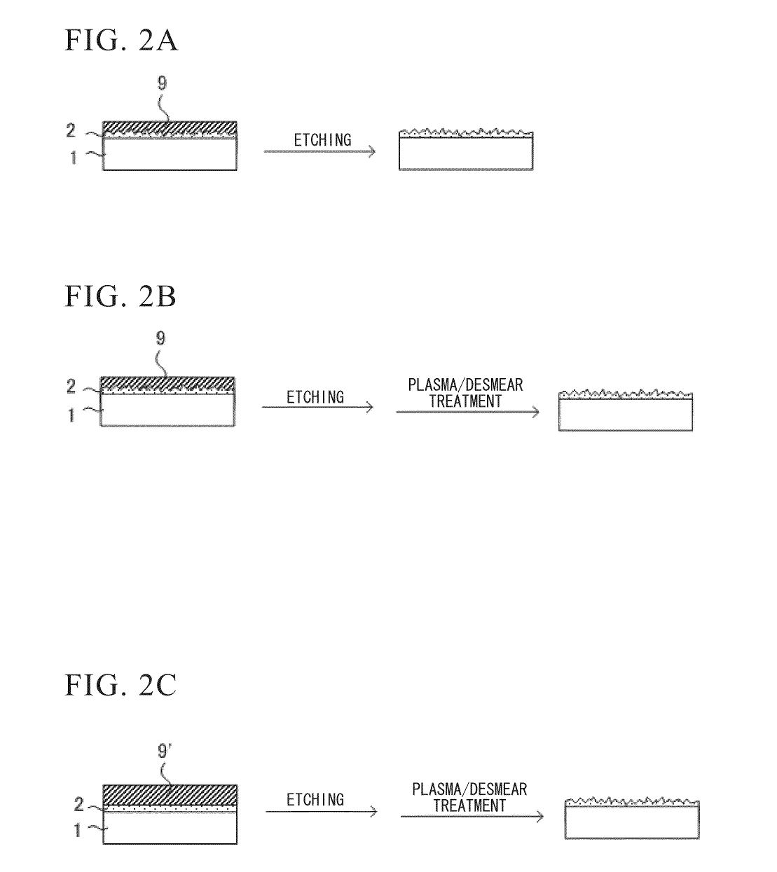

Examples of the method of roughening the primer resin layer include the below-mentioned methods (a) to (c) shown respectively in FIG. 2A to FIG. 2C.

The roughening method (a) shown in FIG. 2A is a method in which a metal foil 9 with roughness is laminated on a primer resin layer 2 by allowing a roughened surface of the metal foil to face a surface of the primer resin layer, and then the metal foil 9 with roughness is removed by etching, thereby roughening the surface of the primer resin layer.

The metal foil 9 with roughness is obtained, for example, by chemically roughening a surface of a copper thin film formed by applying a copper plating treatment to a surface of a metal foil such as a copper foil or an aluminum foil, or a film, or physically roughening the surface using a grinder. From the viewpoint of thinning, a metal foil obtained by roughening a surface of a copper thin film formed by applying a copper plating treatment is preferred.

The roughening method (b) shown in FIG. 2B is a method in which the metal foil 9 with roughness is laminated on a primer resin layer 2 by allowing the roughened surface of the metal foil to face a surface of the primer resin layer, and the metal foil 9 is removed by etching, and then the plasma treatment, the desmear treatment, or both of these surface treatments is/are carried out.

By carrying out the plasma treatment and/or the desmear treatment, smear remaining after roughening the primer resin layer is removed, thus electroless plating adhesion properties are further improved and also the peel strength increases. Smear means an unnecessary resin foreign substance.

The roughening method (c) shown in FIG. 2C is a method in which a non-roughened metal foil 9′ is laminated on a primer resin layer 2 and the metal foil is removed by etching, and then a plasma treatment, a desmear treatment, or both of these surface treatments is/are applied to a surface of the primer resin layer.

It is possible to use, as the non-roughened metal foil 9′, the metal foil 9 with roughness before roughening the surface thereof.

In the methods (b) and (c), a surface treatment of either a plasma treatment or a desmear treatment may be carried out. Preferably, both surface treatments of a plasma treatment and a desmear treatment are carried out. This is because smear on a primer resin layer can be reliably removed.

Among the methods (a) to (c), the method (b) is particularly preferred from the viewpoint of excellent electroless plating adhesion properties and peel strength.

The thickness of the primer resin layer is preferably from 0.5 to 10 μm, and particularly preferably from 2 to 7 μm. When the thickness is within the above range, it is possible to obtain a printed wiring board coping with thinning.

Next, a palladium catalyst 3 is applied to a surface of a primer resin layer 2 in the procedure shown in FIG. 1C, and electroless copper plating is carried out in the procedure shown in FIG. 1D thereby forming an electroless copper plating layer 4.

Next, a circuit non-forming portion is masked by a plating resist 5 on an electroless copper plating layer 4 in the procedure shown in FIG. 1E, and thick copper plating of a circuit forming portion is carried out by electroless copper plating in the procedure shown in FIG. 1F thereby forming an electrolytic copper plated layer 6.

Next, a plating resist 5 is removed in the procedure shown in FIG. 1G, an electroless copper plating layer 4 of a circuit non-forming portion is removed by soft etching in the procedure shown in FIG. 1H thereby forming a conductor circuit 7 on a core base material 1.

Next, a palladium removal treatment of a circuit-forming surface is carried out in the procedure shown in FIG. 1I. By this treatment, a palladium catalyst applied in a SAP process and a palladium metal residue caused thereby are removed. A palladium catalyst 3 in the region covered with a conductor circuit 7 remains even after a palladium removal treatment.

It is possible to select, as the palladium removal treatment after the SAP process, at least one from the group consisting of:

(a) a treatment with a palladium removal agent,
(b) a treatment with a potassium cyanide (KCN)-containing liquid,
(c) a desmear treatment with a chemical liquid, and
(d) a dry desmear treatment with plasma.

The above palladium removal treatments (a) to (d) will be sequentially described below.

(a) Treatment with Palladium Removal Agent

The treatment with a palladium removal agent can be carried out using treatments with two kinds of chemical liquids shown below alone or in combination.

[1] Treatment with Chemical Liquid Containing Nitric Acid and Chlorine Ions

A chemical liquid containing nitric acid and chlorine ions has the action of dissolving palladium metal adhered to a resin surface to remove the palladium metal.

The content of nitric acid in the chemical liquid containing nitric acid and chlorine ions is preferably from 50 to 500 mL/L, and particularly preferably from 100 to 400 mL/L, in terms of 67.5% nitric acid. When the content of nitric acid is less than 50 mL/L, the palladium removal effect is scarcely obtained. In contrast, when the content is more than 500 mL/L, not only is the palladium removal effect not improved, but also the solubility of a copper circuit increases.

Examples of a source of chlorine ions contained in the chemical liquid containing nitric acid and chlorine ions include inorganic chlorides such as hydrochloric acid, sodium chloride, potassium chloride, ammonium chloride, copper chloride, iron chloride, nickel chloride, cobalt chloride, tin chloride, zinc chloride and lithium chloride. Among these inorganic chlorides, hydrochloric acid and sodium chloride are preferred. The content of chlorine ions is preferably from 1 to 60 g/L, and particularly preferably from 5 to 50 g/L, in terms of chlorine ions. When the content of chlorine ions is less than 1 g/L, the palladium removal effect is scarcely obtained. In contrast, when the content is more than 60 g/L, the palladium removal effect is not improved.

It is also possible to add surfactants and NOx inhibitors, which are usually used so as to improve permeability and wettability, to the chemical liquid containing nitric acid and chlorine ions in the amount which does not exert an influence on the removal of palladium.

The chemical liquid containing nitric acid and chlorine ions is adjusted such that pH becomes 1 or less.

[2] Treatment with Sulfur Organic Substance-Containing Liquid

It is considered that a sulfur organic substance can prevent abnormal precipitation since it not only has the action of roughening a resin surface, but also brings a sulfur organic substance into contact with a resin surface thereby making the sulfur organic substance form complex ions with Pd²⁺ adhering to the resin surface, thus enabling deactivation of Pd²⁺.

The sulfur organic substance is not particularly limited as long as it contains sulfur and carbon atoms in a compound. However, the sulfur organic substance does not include those, which contain sulfur but do not contain carbon atoms, such as sodium thiosulfate. Examples of the sulfur organic substance include thiourea derivative, thiols, sulfide, thiocyanates, sulfamic acid or salts thereof.

Specific examples of the thiourea derivative include thiourea, diethylthiourea, tetramethylthiourea, 1-phenyl-2-thiourea, thioacetamide and the like.

Examples of thiols include 2-mercaptoimidazole, 2-mercaptothiazoline, 3-mercapto-1,2,4-triazole, mercaptobenzoimidazole, mercaptobenzoxazole, mercaptobenzothiazole and mercaptopyridine. Examples of the sulfide include 2-aminophenyldisulfide, tetramethylthiuramdisulfide, thiodiglycolic acid and the like.

Examples of thiocyanates include sodium thiocyanate, potassium thiocyanate and ammonium thiocyanate. Examples of the sulfamic acid or salts thereof include sulfamic acid, ammonium sulfamate, sodium sulfamate, potassium sulfamate and the like.

Among these sulfur organic substances, thiols having a mercapto group or thiocyanates having a thiocyan group are preferred.

The concentration of the sulfur organic substance is preferably from 0.1 to 100 g/L, and particularly preferably from 0.2 to 50 g/L.

The sulfur organic substance-containing liquid is adjusted such that pH becomes 10 to 14.

(b) Treatment with Potassium Cyanide (KCN)-Containing Liquid

It is considered that a potassium cyanide (hereinafter sometimes referred to as KCN)-containing liquid can prevent abnormal precipitation since it not only has the action of roughening a resin surface, but also brings a KCN-containing solution into contact with a resin surface to form complex ions [Pd(CN)₃]⁻ of Pd²⁺ and CN⁻, adhering to the resin surface, thus enabling deactivation of Pd²⁺.

It is possible to use, as the KCN-containing liquid, a strong alkali liquid containing only KCN.

The KCN-containing liquid is adjusted such that pH becomes 10 to 14.

(c) Desmear Treatment with Chemical Liquid

A desmear treatment with a chemical liquid is a treatment with a permanganate-containing liquid, and it is possible to roughen a resin surface by an oxidation reaction shown below using a permanganate liquid.

CH₄+12MnO₄⁻+14OH⁻→CO₃²⁻+12MnO₄²⁻+9H₂O+O₂

2MnO₄²⁻+2H₂O→2MnO₂+4OH⁻+O₂

It is possible to use, as the permanganate liquid, for example, Concentrate Compact CP liquid for initial make-up of electrolytic bath (NaMnO₄-containing oxidizing agent, manufactured by Atotech Japan K.K.) in combination with NaOH as an OH⁻ source.

The permanganate-containing liquid is adjusted such that pH becomes 12 to 14.

(d) Dry Desmear Treatment with Plasma

A dry desmear treatment with plasma (hereinafter sometimes referred to as a “plasma treatment”) is a treatment in which smear is allowed to undergo oxidative decomposition and removed from a copper terminal surface by bringing plasma into contact with a surface to be treated and, at the same time, a material of a resin surface supporting a circuit is appropriately removed thereby causing roughening. It is considered that since Pd²⁺ ions adhered to a resin surface in the vicinity of a circuit are removed together with a material of a resin surface by a plasma treatment, abnormal precipitation can be prevented.

It is possible to use, as a plasma treatment device, for example, PCB2800E manufactured by March Plasma Systems, Inc. Examples of specific implemental method and implemental conditions of the plasma treatment include the following.

### <Conditions of Plasma Treatment>

Gas: CF₄/O₂ (mixing of two kinds) or CF₄/O₂/Ar (mixing of three kinds)

Atmospheric pressure: 10 to 500 mTorr

Output: 1,000 W to 10,000 W

Time: 60 to 600 seconds

A palladium removal treatment after a SAP process can be carried out at an optional stage before a gold-plating treatment is carried out after formation of a conductor circuit. In a case a gold-plating treatment is carried out in apart of the conductor circuit formed by an SAP method, it is possible to suppress abnormal precipitation in the gold-plating treatment only by carrying out a palladium removal treatment only in the portion which is desired to be subjected to a gold-plating. For example, in a case a gold-plating treatment of an ENEPIG method or an ENIG method is desired to be carried out only in a terminal portion of the conductor circuit formed by the SAP process, a palladium removal treatment may be carried out only in the region exposed from a solder resist layer after covering the portion other than the terminal portion of the conductor circuit with a solder resist layer.

Next, in the procedure shown in FIG. 1J, a gold-plating treatment is carried out to form a composite gold-plated layer 8 on a surface of the conductor circuit.

The gold-plating treatment is a gold-plating treatment selected from the group consisting of an electroless nickel-palladium-gold-plating treatment (ENEPIG method) and an electroless nickel-gold-plating treatment (ENIG method). By carrying out the gold-plating treatment, a composite gold-plated layer selected from the group consisting of a nickel-palladium-gold-plated layer (Ni—Pd—Au layer) and a nickel-gold-plated layer (Ni—Au layer) is formed on the conductor circuit. Among these treatments, an electroless nickel-palladium-gold-plating treatment (ENEPIG method) is particularly preferred. This is because it is excellent in prevention of oxidation and prevention of diffusion of nickel and also has heat resistance and can decrease a film thickness of gold.

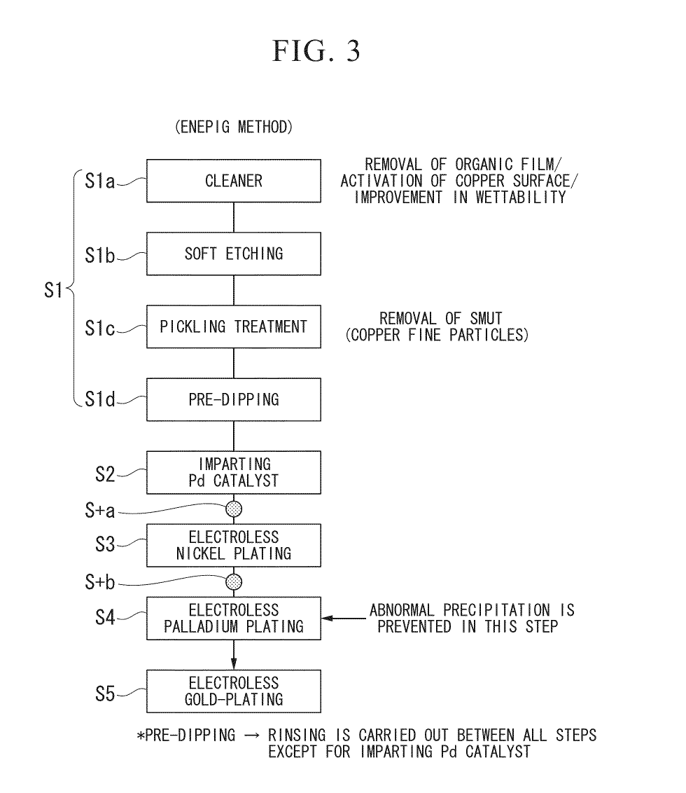

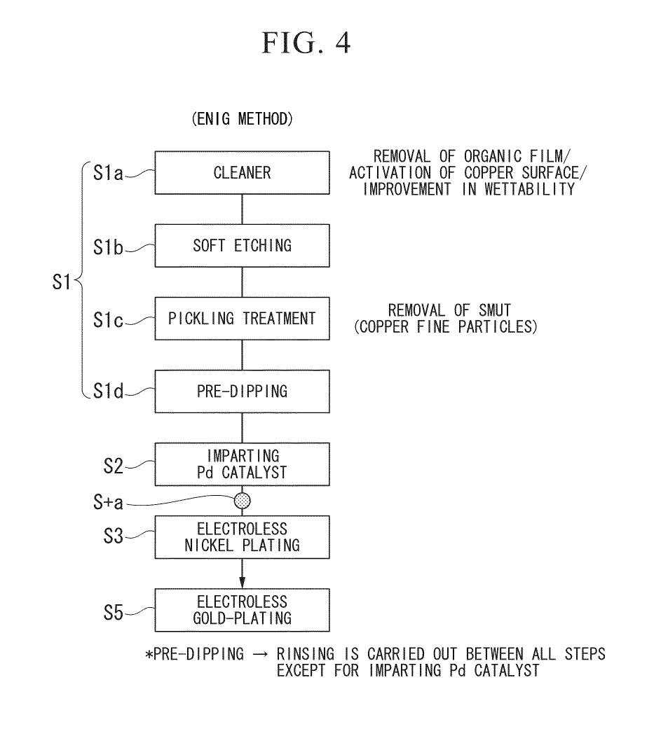

FIG. 3 is a block diagram showing a procedure of an electroless nickel-palladium-gold-plating treatment (ENEPIG method), and FIG. 4 is a block diagram showing a procedure of an electroless nickel-gold-plating treatment (ENIG method).

In a case an ENEPIG method or an ENIG method is carried out in the present invention, a surface treatment can be carried out in the terminal portion by one, or two or more methods, if necessary, as a pretreatment before a palladium catalyst-imparting step. In the drawing, cleaner (S1a), soft etching (S1b), acid treatment (S1c) and pre-dipping (S1d) are shown as a pretreatment, but other treatments may also be carried out.

After the pretreatment, imparting a palladium catalyst and an ENEPIG method or an ENIG method are carried out thereby forming a composite gold-plated layer (Ni—Pd—Au layer or Ni—Au layer).

Unless otherwise specified, the procedure of the ENEPIG method will be described. With respect to the ENIG method, the procedure is essentially the same as that of ENEPIG method, except that the step of an electroless palladium-plating treatment (S4) is not carried out.

In the ENEPIG method, a pretreatment (S1), a palladium catalyst-imparting step (S2), an electroless nickel-plating treatment (S3), an electroless palladium-plating treatment (S4) and an electroless gold-plating treatment (S5) may be carried out in a conventional manner.

### <Pretreatment (S1)>

### (1) Cleaner Treatment (S1a)

A cleaner treatment (S1a) as one of pretreatments is carried out so as to carry out removal of an organic film from a terminal surface, metal activation of a terminal surface, and an improvement in wettability of a terminal surface by bringing an acidic type or alkali type cleaner liquid into contact with a terminal surface.

An acidic type cleaner is configured to mainly etch a very thin portion of a terminal surface to activate the surface. A liquid containing oxycarboxylic acid, ammonia, a salt and a surfactant (for example, ACL-007 of Uyemura & CO., LTD.) is used as the acidic type cleaner which is effective for a copper terminal.

A liquid containing sulfuric acid, a surfactant and sodium chloride (for example, ACL-738 of Uyemura & CO., LTD.) may be used as another acidic type cleaner which is effective for a copper terminal, and this liquid has high wettability.

An alkali type cleaner is configured to mainly remove an organic film, and a liquid containing a nonionic surfactant, 2-ethanolamine and diethylenetriamine (for example, ACL-009 of Uyemura & CO., LTD.) is used as the cleaner which is effective for a copper terminal.

To carry out a cleaner treatment, any one of the above-mentioned cleaner liquids is brought into contact with a terminal portion by a method such as dipping or spraying, followed by rinsing.

### (2) Soft Etching Treatment (S1b)

A soft etching treatment (S1b) as another pretreatment is carried out so as to remove an oxide film by etching a very thin portion of a terminal surface. An acidic liquid containing sodium persulfate and sulfuric acid is used as a soft etching liquid which is effective for a copper terminal.

To carry out a soft etching treatment, the above soft etching liquid may be brought into contact with a terminal portion by a method such as dipping or spraying, followed by rinsing.

### (3) Pickling Treatment (S1c)

A pickling treatment (S1c) as another pretreatment is carried out so as to remove smut (copper fine particles) from a terminal surface or a resin surface in the vicinity thereof.

Sulfuric acid is used as a pickling liquid which is effective for a copper terminal.

To carry out a pickling treatment, the above pickling liquid may be brought into contact with a terminal portion by the method such as dipping or spraying, followed by rinsing.

### (4) Pre-Dipping Treatment (S1d)

A pre-dipping treatment (S1d) as another pretreatment is a treatment of dipping in sulfuric acid having almost the same concentration as a catalyst-imparting liquid before a palladium catalyst-imparting step. The treatment is carried out so as to improve adhesion to Pd ions contained in the catalyst-imparting liquid by increasing hydrophilicity of a terminal surface, or enable repeated recycling of the catalyst-imparting liquid by avoiding wash water from flowing into the catalyst-imparting liquid, or remove an oxide film. Sulfuric acid is used as a pre-dipping liquid.

To carry out a pre-dipping treatment, a terminal portion is dipped in the above pre-dipping liquid. Rinsing is not carried out after a pre-dipping treatment.

### <Palladium Catalyst-Imparting Step (S2)>

An acidic liquid containing Pd²⁺ ions (catalyst-imparting liquid) is brought into contact with a terminal surface thereby to substitute Pd²⁺ ion with metal Pd on a terminal surface according to ionization tendency (Cu+Pd²+→Cu²⁺+Pd). Pd adhered to a terminal surface acts as a catalyst of electroless plating. Palladium sulfate or palladium chloride can be used as a palladium salt which is a Pd²⁺ ion source.

Palladium sulfate is suited for formation of a thin wire since it has weak adsorption power as compared with palladium chloride and is likely to undergo removal of Pd. It is possible to use, as a liquid for imparting a palladium sulfate-based catalyst which is effective for a copper terminal, a strong acid liquid containing sulfuric acid, a palladium salt and a copper salt (for example, KAT-450 of Uyemura & CO., LTD.), and a strong acid liquid containing oxycarboxylic acid, sulfuric acid and a palladium salt (for example, MNK-4 of Uyemura & CO., LTD.).

In contrast, since palladium chloride has strong adsorption power and exchange property and is less likely to undergo removal of Pd, the effect of preventing unplating can be obtained when electroless plating is carried out under the conditions where unplating is likely to arise.

To carry out the palladium catalyst-imparting step, the above catalyst-imparting liquid may be brought into contact with a terminal portion by the method such as dipping or spraying, followed by rinsing.

### <Electroless Nickel-Plating Treatment (S3)>

It is possible to use, as an electroless nickel-plating bath, for example, a plating bath containing a water-soluble nickel salt, a reducing agent and a complexing agent. Details of the electroless nickel-plating bath are disclosed, for example, in Japanese Unexamined Patent Application, First Publication No. Hei 8-269726.

Nickel sulfate, nickel chloride and the like are used as the water-soluble nickel salt, and the concentration is adjusted to about 0.01 to 1 mol/liter.

Hypophosphite such as hypophosphoric acid or sodium hypophosphite, dimethylamineborane, trimethylamineborane, hydrazine and the like are used as the reducing agent, and the concentration is adjusted to about 0.01 to 1 mol/liter.

Carboxylic acids such as malic acid, succinic acid, lactic acid, citric acid, and a sodium salt thereof; amino acids such as glycine, alanine, iminodiacetic acid, arginine and glutamic acid are used as the complexing agent, and the concentration is adjusted to about 0.01 to 2 mol/liter.

This plating bath is used at pH adjusted to 4 to 7 and a bath temperature adjusted to about 40 to 90° C. When hypophosphoric acid is used as the reducing agent in this plating bath, a main reaction shown below proceeds by a Pd catalyst on a copper terminal surface to form a Ni-plated film.

Ni²⁺+H₂PO₂⁻+H₂O+2e⁻→Ni+H₂PO₃⁻+H₂

### <Electroless Palladium-Plating Treatment (S4)>

It is possible to use, as an electroless palladium plating bath, for example, a plating bath containing a palladium compound, a complexing agent, a reducing agent and an unsaturated carboxylic acid compound.

For example, palladium chloride, palladium sulfate, palladium acetate, palladium nitrate, tetraamminepalladium hydrochloride and the like are used as a palladium compound, and the concentration is adjusted to about 0.001 to 0.5 mol/liter, based on palladium.

Ammonia, or an amine compound such as methylamine, dimethylamine, methylenediamine or EDTA is used as a complexing agent, and the concentration is adjusted to about 0.001 to 10 mol/liter.

Hypophosphoric acid, or a hypophosphite such as sodium hypophosphite or ammonium hypophosphite is used as a reducing agent, and the concentration is adjusted to about 0.001 to 5 mol/liter.

An unsaturated carboxylic acid such as acrylic acid, methacrylic acid or maleic acid, an anhydride thereof, a salt such as a sodium salt thereof or an ammonium salt, or a derivative such as an ethyl ester thereof or a phenyl ester thereof is used as an unsaturated carboxylic acid compound, and the concentration is adjusted to about 0.001 to 10 mol/liter.

This plating bath is used at pH adjusted to 4 to 10 and a bath temperature adjusted to about 40 to 90° C. When hypophosphoric acid is used as the reducing agent in this plating bath, a main reaction shown below proceeds on a copper terminal surface to form a Pd-plated film.

Pd²⁺+H₂PO₂⁻+H₂O→Pd+H₂PO₃⁻+2H⁺

### <Electroless Gold-Plating Treatment (S5)>

For example, a plating bath containing a water-soluble gold compound, a complexing agent and an aldehyde compound can be used as an electroless gold-plating bath. Details of the electroless gold-plating bath are disclosed, for example, in Japanese Unexamined Patent Application, First Publication No. 2008-144188.

For example, gold cyanide, a gold cyanide salt such as gold potassium cyanide, gold sodium cyanide or gold ammonium cyanide is used as a water-soluble gold compound, and the concentration is adjusted to about 0.0001 to 1 mol/liter, based on gold.

For example, phosphoric acid, boric acid, citric acid, gluconic acid, tartaric acid, lactic acid, malic acid, ethylenediamine, triethanolamine, ethylenediaminetetraacetic acid and the like are used as a complexing agent, and the concentration is adjusted to about 0.001 to 1 mol/liter.

For example, an aliphatic saturated aldehyde such as formaldehyde or acetaldehyde, an aliphatic dialdehyde such as glyoxal or succindialdehyde, an aliphatic unsaturated aldehyde such as crotonaldehyde, an aromatic aldehyde such as benzaldehyde, o-, m- or p-nitrobenzaldehyde, saccharides having an aldehyde group (—CHO), such as glucose and galactose are used as an aldehyde compound (reducing agent), and the concentration is adjusted to about 0.0001 to 0.5 mol/liter.

This plating bath is used at pH adjusted to 5 to 10 and a bath temperature adjusted to about 40 to 90° C. When this plating bath is used, two substitution reactions shown below proceed on a copper terminal surface to form an Au-plated film.

Pd+Au⁺→Pd²⁺+Au+e⁻

e⁻ (obtained by oxidizing a component in a plating bath by an Au autocatalytic action)+Au⁺→Au

It is preferred that a palladium catalyst be applied on a surface of the metal fine pattern in the gold-plating treatment step, and then the printed wiring board be subjected to at least one second palladium removal treatment selected from the group consisting of:

(e) a treatment with a solution at pH 10 to 14, and
(f) a dry desmear treatment with plasma, in an optional stage before an electroless nickel-plating treatment or an electroless palladium-plating treatment is carried out.

Specifically, when an ENEPIG process in FIG. 3 is carried out, a second palladium removal treatment can be carried out at a stage (S+a) between the palladium catalyst-imparting step and the electroless nickel-plating treatment, and a stage (S+b) between the electroless nickel-plating treatment and the electroless palladium-plating treatment.

When an ENIG process in FIG. 4 is carried out, a second palladium removal treatment can be carried out at a stage (S+a) between the palladium catalyst-imparting step and the electroless nickel-plating treatment.

The above second palladium removal treatment (e) or (f) is configured to appropriately remove a material of a resin surface supporting a conductor circuit thereby roughening the resin surface. It is considered that Pd²⁺ ions adhered to a resin surface in the vicinity of a circuit are removed by the treatment, together with a material of the resin surface, thus enabling prevention of abnormal precipitation.

A treatment with a solution of pH 10 to 14 (e), and a dry desmear treatment with plasma (f) will be sequentially described.

In the treatment with a solution of pH 10 to 14 (e), any one or two or more of (e-1) to (e-4) shown below can be carried out.

(e-1) Treatment with Sodium Hydroxide-Containing Liquid

It is possible to use, as a sodium hydroxide-containing liquid, an aqueous simple solution of NaOH after adjusting to the concentration such that pH preferably becomes 10 to 14, and more preferably 11 to 13 (strong alkali).

A mixed solution comprising NaOH and an acidic ethylene glycol-based solvent-containing liquid such as an alkali buffer liquid for wetting NaOH-containing surface may also be used as long as the mixed solution has a concentration such that it becomes strong alkali of pH 10 to 14. Examples of the ethylene glycol-based solvent-containing liquid to be mixed with NaOH include Swelling Dip Securiganth P liquid for initial make-up of electrolytic bath, manufactured by Atotech Japan K.K.

(e-2) Desmear Treatment with Chemical Liquid

The same as the desmear treatment with a chemical liquid (c).

(e-3) Treatment with Sulfur Organic Substance-Containing Liquid

The same as the treatment with a sulfur organic substance-containing liquid [2] in (a). The sulfur organic substance-containing liquid is suited for use in the second palladium removal treatment since it deactivates palladium on a resin and does not react with palladium on a copper circuit.

(e-4) Treatment with Potassium Cyanide (KCN)-Containing Liquid

The same as the treatment with a potassium cyanide (KCN)-containing liquid (b).

(f) Dry Desmear Treatment with Plasma

The same as the dry desmear treatment with plasma (d).

According to the present invention, a primer resin layer having surface roughness represented by the arithmetic average of 0.5 μm or less was provided on a resin surface on which a metal fine pattern is desired to be formed, and then a series of the steps (palladium catalyst-imparting, electroless metal-plating and electrolytic metal-plating) of SAP are carried out. Therefore, an electroless metal-plating layer is formed on a resin surface having satisfactory adhesion of a palladium catalyst and uniform dense irregularities. Accordingly, a surface of a base material made of a resin is excellent in electroless plating adhesion properties, thus a metal fine pattern having excellent peel strength is formed.

The resin surface having excellent electroless plating adhesion properties has a problem in that when the metal fine pattern formed on the resin surface is subjected to a gold-plating treatment by an ENIG method or an ENEPIG method, abnormal precipitation of metal is likely to arise. However, according to the present invention, it is possible to suppress abnormal precipitation of metal during a gold-plating treatment by carrying out the first palladium removal treatments (a) to (d) before carrying out a gold-plating treatment.

According to the ENEPIG method, it is possible to suppress abnormal precipitation of metal during a gold-plating treatment by carrying out the second palladium removal treatment (e) or (f), until electroless palladium plating is carried out after imparting a palladium catalyst in the case of the ENEPIG method, or until electroless nickel plating is carried out after imparting a palladium catalyst in the case of the ENIG method.

A semiconductor device can be manufactured by mounting a semiconductor on a printed wiring board of the present invention. The semiconductor device is excellent in inter-wiring insulation reliability and connection reliability by use of a printed wiring board obtained by a method for manufacturing a base material having a gold-plated metal fine pattern of the present invention.

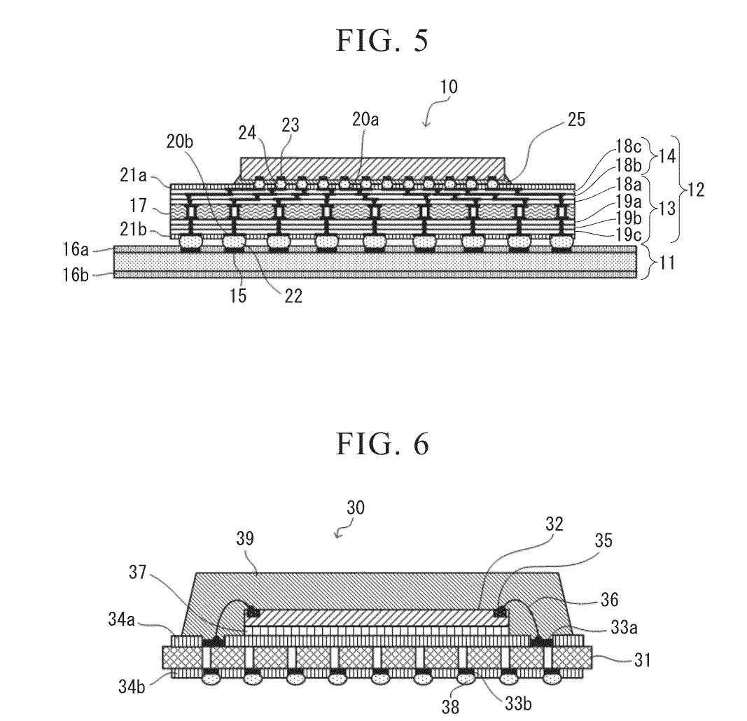

It is also possible to manufacture a semiconductor device by using an interposer obtained by the present invention as a package substrate, mounting and connecting a semiconductor element thereto, followed by sealing. Configurations of the semiconductor device using an interposer as a package substrate include those shown in FIG. 5 and FIG. 6 below.

FIG. 5 is a view schematically showing an example of amounted layered structure of a semiconductor device according to an embodiment of the present invention, and the semiconductor device is a semiconductor device in which a semiconductor package using an interposer as a package substrate is mounted in a motherboard.

Although both sides of a motherboard 11 are covered with solder resist layers 16a, 16b, a connection terminal 15 of an outermost layer circuit on the side for connecting a semiconductor package is exposed from a solder resist layer 16a.

A semiconductor package 12 is an area array type package in which connection terminals 20b are arranged on a package lower surface, and a connection terminal 20b of a package lower surface and connection terminal 15 on the side for mounting a package of a motherboard 11 undergo solder connection by a solder ball 22.

The semiconductor package 12 includes an interposer 13 as a package substrate, and a semiconductor element 14 mounted on the interposer.

The interposer 13 is a multi-layer printed wiring board, in which three layers of conductor circuit layers 18a, 18b, 18c are sequentially laminated on the side for mounting a semiconductor element of a core substrate 17 thereof, and also three layers of conductor circuit layers 19a, 19b, 19c are sequentially laminated on the side for connecting a motherboard. The side for mounting a semiconductor element of an interposer 13 pass through three layers of conductor circuit layers 18a, 18b, 18c, thus stepwisely decreasing wiring dimension. Although an outermost layer circuit on both sides of an interposer 13 are covered with solder resist layers 21a, 21b, connection terminals 20a, 20b are exposed from solder resist layers 21a, 21b.

Line-and-space of a connection terminal 20a of an outermost layer circuit on the side for mounting a semiconductor element of an interposer 13 is preferably 10 to 50 μm/10 to 50 μm, and more preferably 12 to 30 μm/12 to 30 μm.

In contrast, line-and-space of a terminal portion 20b of an outermost layer circuit on the side for connecting a motherboard of an interposer 13 is preferably 300 to 500 μm/300 to 500 μm, and more preferably 350 to 450 μm/350 to 450 μm.

Line-and-space of a connection terminal 15 of an outermost layer circuit on the side for mounting a package (side for connecting an interposer) of a motherboard 11 is also preferably 300 to 500 μm/300 to 500 μm, and more preferably 350 to 450 μm/350 to 450 μm.

A semiconductor element 14 includes an electrode pad 23 on a lower surface, and this electrode pad 23 and a connection terminal 20a of an outermost layer circuit on the side for mounting a semiconductor element of an interposer 13 undergo solder connection by a solder ball 24.

The space gap between the interposer 13 and the semiconductor element mounted thereon is sealed with a sealing material 25 such as an epoxy resin.

The outermost layer circuit 18c on the side for mounting a semiconductor element of an interposer 13 shown in FIG. 5 is formed by the method of the present invention, thus a connection terminal 20a can be subjected to a gold-plating treatment by the method of the present invention.

FIG. 6 is a view schematically showing a structure of another type of a semiconductor package (wire bonding type) using an interposer as a package substrate.

In FIG. 6, a semiconductor package 30 includes an interposer 31 as a package substrate, and a semiconductor element 32 mounted on the interposer.

The semiconductor package 30 is an area array type package in which connection terminals 33b are arranged on a package lower surface, and solder balls 38 are disposed on connection terminals 33b of the package lower surface.

Although detailed laminate structure of the interposer 31 is omitted, the interposer is a multi-layer printed wiring board similar to the interposer shown in FIG. 5. Although an outermost layer circuit of both sides is covered with solder resist layers 34a, 34b, connection terminals 33a, 33b are exposed from solder resist layers 34a, 34b.

Regarding a semiconductor element 32, the semiconductor element 32 is fixed on the side for mounting a semiconductor element of an interposer 31 through a die-bonding material cured layer 37 made of an epoxy resin.

The semiconductor element 32 includes an electrode pad 35 on a top surface, and the electrode pad 35 is connected to connection terminal 33a of an outermost layer circuit on the side for mounting a semiconductor element of an interposer 31 using a gold wire 36.

The side for mounting a semiconductor element of a semiconductor package 31 is sealed with a sealing material 39 such as an epoxy resin.

An outermost layer circuit on the side for mounting a semiconductor element of the interposer 31 shown in FIG. 6 is formed by the method of the present invention, thus the connection terminal 33a can be subjected to gold-plating treatment by the method of the present invention.

A conductor circuit of an outermost layer on the side for connecting a motherboard of an interposer and a conductor circuit of an outermost layer on the side for connecting an interposer of a motherboard are formed by the method of the present invention in the same manner as mentioned above, and then only a terminal portion is exposed and other portions are covered with a solder resist layer, and a gold-plating treatment can be carried out to the terminal portion by the method of the present invention.

The method for manufacturing a base material having a gold-plated metal fine pattern of the present invention can be suitably carried out with respect to, in addition to the above-mentioned printed wiring board, a base material having a gold-plated metal fine pattern of electronic components other than a printed wiring board, and a base material having a gold-plated metal fine pattern in various fields other than electronic components.

### EXAMPLES

The present invention will be described in more detail below by way of Examples, but is not limited thereto. Additions of constitutions, omissions, substitutions, and other modifications can be made without departing from the spirit or scope of the present invention.

### Example 1

### Treatment (a), ENEPIG Step

### 1. Preparation of Primer Resin

31.5 parts by weight of a methoxynaphthalenearalkyl type epoxy resin (EPICLON HP-5000, manufactured by DIC Corporation,) as an epoxy resin, 26.7 parts by weight of a phenol novolak type cyanate resin (Primaset PT-30, manufactured by Lonza Inc.) as a cyanate ester resin, 31.5 parts by weight of a polyamide resin (KAYAFLEX BPAM01, manufactured by Nippon Kayaku Co., Ltd.) and 0.3 part by weight of imidazole (CUREZOL 1B2PZ, manufactured by Shikoku Chemical Corporation) as a curing catalyst were dissolved by stirring in a mixed solvent of dimethylacetamide and methyl ethyl ketone for 30 minutes. Furthermore, 0.2 part by weight of an epoxysilane-coupling agent (A187, manufactured by Nippon Unicar Company Limited) as a coupling agent and 9.8 parts by weight of spherical fused silica (SP-7 having an average particle size of 0.75 μm, manufactured by Fuso Chemical Co., Ltd.) as an inorganic filler were added, followed by stirring for 10 minutes using a high-speed stirrer to prepare a resin varnish.

### 2. Manufacture of Primer Resin Sheet

The resin varnish obtained above was applied on an electrolytic copper foil layer of a peelable type copper foil (YSNAP-3B, manufactured by Nippon Denkai, Ltd., carrier foil layer: copper foil (18 μm), electrolytic copper foil layer (3 μm), surface roughness Ra (0.4 μm)) obtained by bonding a peelable carrier foil layer and an electrolytic copper foil layer having a thickness of 0.5 to 5.0 μm together using a comma coater such that a resin layer after drying had a thickness of 5 μm, and then dried by a dryer at 150° C. for 10 minutes to manufacture a primer resin sheet with a copper foil.

### 3. Manufacture of Core Material

A 0.1 mm thick prepreg (GEA-679FG, manufactured by Hitachi Chemical Co., Ltd.) was set such that a primer layer of the obtained resin sheet faces inward and the prepreg was cured by heating and pressed under pressure in a vacuum, and then a carrier foil layer was removed to manufacture a laminated sheet with a 3-μm thick electrolytic copper foil and a 5-μm thick primer layer.

### 4. Manufacture of Test Piece

(1) The 3-μm thick copper foil of the copper-clad laminate obtained above was removed by etching thereby to expose a primer layer.

### (2) Desmear Treatment of Primer Layer Surface

A substrate with the exposed primer layer was subjected to a surface treatment using an alkali buffer liquid for wetting NaCH-containing surface and sodium permanganate-containing liquid by the procedure shown below.

Resin surface swelling treatment: A substrate was dipped in a mixed liquid (pH 12) of commercially available sodium hydroxide at a liquid temperature of 60° C. and an ethylene glycol-based solvent-containing liquid (Swelling Dip Securiganth P liquid for initial make-up of electrolytic bath, manufactured by Atotech Japan K.K.) for 2 minutes, and then washed three times with water.

Resin Surface Roughening Treatment: After a swelling treatment, a substrate was dipped in a sodium permanganate-containing roughening treatment liquid (Concentrate Compact CP liquid for initial make-up of electrolytic bath, manufactured by Atotech Japan K.K.) at a liquid temperature 80° C. for 2 minutes, and then washed three times with water.

Neutralization Treatment: After a roughening treatment, a substrate was dipped in a neutralization treatment liquid (Reduction Securiganth P500 liquid for initial make-up of electrolytic bath, manufactured by Atotech Japan K.K.) at a liquid temperature of 40° C. for 3 minutes, and then washed three times with water.

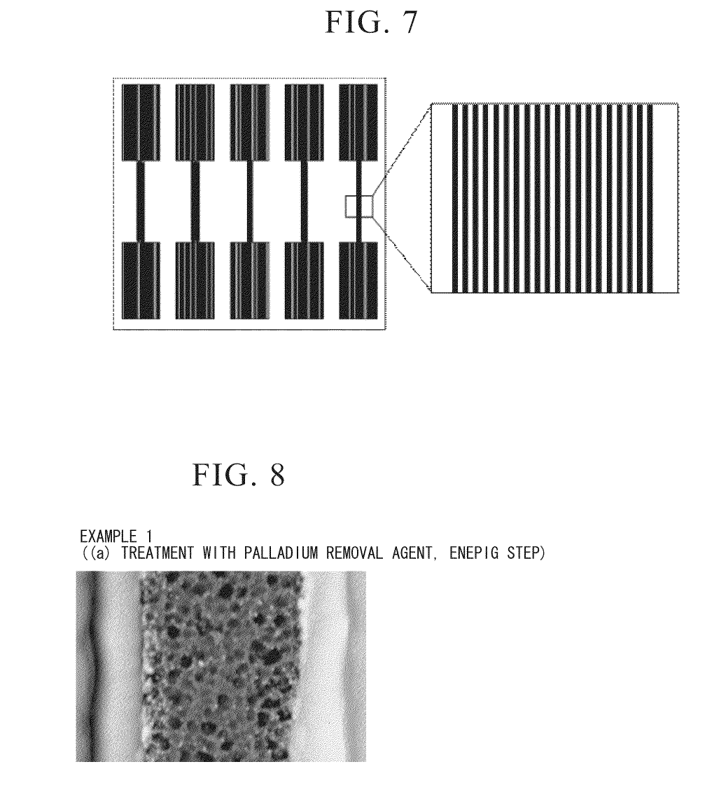

(3) On a surface of a primer layer subjected to a desmear treatment, an electroless copper plating layer (THRU-CUP PEA process, manufactured by Uyemura & CO., LTD.) was formed in a target thickness of 1 μm.
(4) On a copper foil surface of a copper-clad laminate, a semi-additive dry film (UFG-255, manufactured by Asahi Kasei Corporation) was laminated by a roll laminator.
(5) The dry film was exposed in accordance with a predetermined pattern shape (parallel light exposure device: EV-0800 manufactured by ONO SOKKI CO., LTD., exposure conditions: exposure dose of 140 mJ, holding time of 15 minutes), followed by development (developing solution: aqueous 1% sodium carbonate solution, developing time: 40 seconds). An electrolytic copper plating treatment was applied to the pattern-shaped exposed area to form a 20-μm thick electrolytic copper-plated film, and then the dry film was peeled (remover: R-100, manufactured by Mitsubishi Gas Chemical Company, Inc., peeling time: 240 seconds).
(6) After peeling, a 1-μm electroless copper seed layer was removed by a flash etching treatment (SAC process, manufactured by EBARA DENSAN LTD.).
(7) Thereafter, a circuit-roughening treatment (roughening treatment liquid: CZ8101, manufactured by MEC Company Ltd., 1 μm roughening conditions) to produce a test piece having a comb tooth pattern-shaped copper circuit of line-and-space (L/S)=20 μm/30 μm. The comb tooth pattern-shaped copper circuit formed on the test piece is shown in FIG. 7.

### 5. Surface Treatment Step

The test piece obtained above was subjected to a surface treatment using an aqueous solution (chemical liquid containing nitric acid and chlorine ions) containing 67.5% nitric acid (300 mL/L), 35% hydrochloric acid (10 mL/L) and a cationic polymer (EPOMIN, manufactured by Nippon Shokubai Co., Ltd., 0.5 g/L), and then washed three times with water (treatment with a palladium removal agent).

### 6. ENEPIG Step

### (1) Cleaner Treatment

Using ACL-007 manufactured by Uyemura & CO., LTD. as a cleaner liquid, the above test piece was dipped in a cleaner liquid at a liquid temperature of 50° C. for 5 minutes, and then washed three times with water.

### (2) Soft Etching Treatment

After the cleaner treatment, using a mixed liquid of sodium persulfate and sulfuric acid as a soft etching liquid, the above test piece was dipped in the soft etching liquid at a liquid temperature of 25° C. for 1 minute, and then washed three times with water.

### (3) Pickling Treatment

After the soft etching treatment, the above test piece was dipped in sulfuric acid at a liquid temperature of 25° C. for 1 minute, and then washed three times with water.

### (4) Pre-Dipping Treatment

After the pickling treatment, the above test piece was dipped in sulfuric acid at a liquid temperature of 25° C. for 1 minute.

### (5) Palladium Catalyst-Imparting Step

After the pre-dipping treatment, KAT-450 manufactured by Uyemura & CO., LTD. was used as a palladium catalyst-imparting liquid so as to impart a palladium catalyst to a terminal portion. The above test piece was dipped in the palladium catalyst-imparting liquid at a liquid temperature of 25° C. for 2 minutes, and then washed three times with water.

### (6) Electroless Ni-Plating Treatment

After the palladium catalyst-imparting step, the above test piece was dipped in an electroless Ni-plating bath (NPR-4, manufactured by Uyemura & CO., LTD.) at a liquid temperature of 80° C. for 35 minutes, and then washed three times with water.

### (7) Electroless Pd-Plating Treatment

After the electroless Ni plating treatment, the above test piece was dipped in an electroless Pd-plating bath (TPD-30, manufactured by Uyemura & CO., LTD.) at a liquid temperature of 50° C. for 5 minutes, and then washed three times with water.

### (8) Electroless Au-Plating Treatment

After the electroless Pd-plating treatment, the above test piece was dipped in an electroless Au-plating bath (TWX-40, manufactured by Uyemura & CO., LTD.) at a liquid temperature of 80° C. for 30 minutes, and then washed three times with water.

### Example 2

### Treatment (b), ENEPIG Step

In the surface treatment step of Example 1, a surface treatment using a chemical liquid containing nitric acid and chlorine ions was not carried out, and a test piece was dipped in a KCN-containing liquid having a concentration of 20 g/liter at a liquid temperature of 25° C. for 1 minute, and then washed three times with water (treatment with KCN).

### Example 3

### Treatment (c), ENEPIG Step

In the surface treatment step of Example 1, a surface treatment using a chemical liquid containing nitric acid and chlorine ions was not carried out, and a desmear treatment with a chemical liquid (surface treatment with a sodium permanganate-containing liquid) was carried out by the procedure shown below.

### (1) Resin Surface Swelling Treatment

A test piece was dipped in a mixed liquid (pH 12) of commercially available sodium hydroxide and an ethylene glycol-based solvent-containing liquid (Swelling Dip Securiganth P liquid for initial make-up of electrolytic bath, manufactured by Atotech Japan K.K.) at a liquid temperature of 60° C. for 2 minutes, and then washed three times with water.

### (2) Resin Surface Roughening Treatment

A test piece was dipped in a sodium permanganate-containing roughening treatment liquid (Concentrate Compact CP liquid for initial make-up of electrolytic bath, manufactured by Atotech Japan K.K.) at a liquid temperature of 60° C. for 1 minute, and then washed three times with water.

### (3) Neutralization Treatment

After the roughening treatment, a test piece was dipped in a neutralization treatment liquid (Reduction Securiganth P500 liquid for initial make-up of electrolytic bath, manufactured by Atotech Japan K.K.) at a liquid temperature of 40° C. for 3 minutes, and then washed three times with water.

### Example 4

### (d) Treatment, ENEPIG Step

In the surface treatment step of Example 1, a surface treatment using a chemical liquid containing nitric acid and chlorine ions was not carried out, and a dry desmear treatment with plasma was carried out by the device under the conditions shown below.

Treatment device: PCB2800E (manufactured by March Plasma Systems, Inc.)

Treatment conditions: gas (mixing of two kinds): O₂ (95%)/CF₄ (5%), atmospheric pressure: 250 mTorr, wattage: 2,000 W, time: 75 seconds

### Example 5

### (a) Treatment, ENIG Step

The same operation as in Example 1 was carried out, except that an electroless Pd-plating treatment (TPD-30, manufactured by Uyemura & CO., LTD.) of the ENEPIG step was not carried out, and the ENEPIG step was changed to the ENIG step in the step of Example 1.

### Example 6

### (b) Treatment, ENIG Step

In the surface treatment step of Example 5, a surface treatment using a chemical liquid containing nitric acid and chlorine ions was not carried out, and a test piece was dipped in a KCN-containing liquid having a concentration of 20 g/liter at a liquid temperature of 25° C. for 1 minute, and then washed three times with water (treatment with KCN).

### Example 7

### (c) Treatment, ENIG Step

In the surface treatment step of Example 5, a surface treatment using a chemical liquid containing nitric acid and chlorine ions was not carried out, and a desmear treatment (c) with a chemical liquid (surface treatment using a sodium permanganate-containing liquid) was carried out by the same procedure as in Example 3.

### Example 8

### (d) Treatment, ENIG Step

In the surface treatment step of Example 5, a surface treatment using a chemical liquid containing nitric acid and chlorine ions was not carried out, and a dry desmear treatment with plasma was carried out using the same device and conditions as in Example 4.

### Example 9

### (a) Treatment, (e-1) Treatment in ENEPIG Step S+a

In the ENEPIG step of Example 1, a test piece was dipped in a mixed liquid (pH 12) of commercially available sodium hydroxide and an ethylene glycol-based solvent-containing liquid (Swelling Dip Securiganth P liquid for initial make-up of electrolytic bath manufactured by Atotech Japan K.K.) at a liquid temperature of 60° C. for 10 minutes at a stage after imparting an electroless Pd catalyst and before electroless nickel plating, and then washed three times with water.

### Example 10

### (a) Treatment, (e-2) Treatment in ENEPIG Step S+a

In the ENEPIG step of Example 1, a test piece was dipped in a sodium permanganate-containing roughening treatment liquid (Concentrate Compact CP liquid for initial make-up of electrolytic bath, Atotech Japan K.K., pH 14) at a liquid temperature of 80° C. for 2 minutes at a stage after imparting an electroless Pd catalyst and before electroless nickel plating, and then washed three times with water.

### Example 11

### (a) Treatment, (e-3) Treatment in ENEPIG Step S+a

In the ENEPIG step of Example 1, a test piece was subjected to a surface treatment using a sulfur organic substance-containing liquid (aqueous solution of mercaptothiazoline (1 g/liter), pH 12.5) at a stage after imparting an electroless Pd catalyst and before electroless nickel plating, and then washed three times with water.

### Example 12

### (a) Treatment, (e-4) Treatment in ENEPIG Step S+a

In the ENEPIG step of Example 1, a test piece was dipped in a KCN-containing liquid (pH 12) having a concentration of 20 g/liter at a liquid temperature of 25° C. for 1 minute at a stage after imparting an electroless Pd catalyst and before electroless nickel plating, and then washed three times with water.

### Example 13

### (a) Treatment, (f) Treatment in ENEPIG Step S+a

In the ENEPIG step of Example 1, a plasma treatment was carried out at a stage after imparting an electroless Pd catalyst and before electroless nickel plating by the device under the conditions shown below.

Treatment device: PCB2800E (manufactured by March Plasma Systems, Inc.)

Treatment conditions: gas (mixing of two kinds): O₂ (95%)/CF₄ (5%), atmospheric pressure: 250 mTorr, wattage: 2,000 W, time: 75 seconds

### Example 14

### (a) Treatment, (e-4) Treatment in ENEPIG Step S+b

In the ENEPIG step of Example 1, a test piece was dipped in a test piece was dipped in a KCN-containing liquid (pH 12) having a concentration of 20 g/liter at a liquid temperature of 25° C. for 1 minute at a stage after electroless nickel plating and before electroless palladium plating, and then washed three times with water.

### Example 15

### (a) Treatment, (e-4) Treatment in ENIG Step S+b

In the ENIG step of Example 5, a test piece was dipped in a test piece was dipped in a KCN-containing liquid (pH 12) having a concentration of 20 g/liter at a liquid temperature of 25° C. for 1 minute at a stage after electroless nickel plating and before electroless palladium plating, and then washed three times with water.

### Comparative Example 1

### No Palladium Removal Treatment, ENEPIG Step

The same operation as in Example 1 was carried out, except that a surface treatment step was not carried out.

### Comparative Example 2

### No Palladium Removal Treatment, ENIG Step

The same operation as in Example 5 was carried out, except that a surface treatment step was not carried out.

### (Evaluation)

Each terminal portion of plated materials obtained in the respective Examples and Comparative Examples was observed by an electron micrograph (reflection electron image) and inter-wiring quality was evaluated.

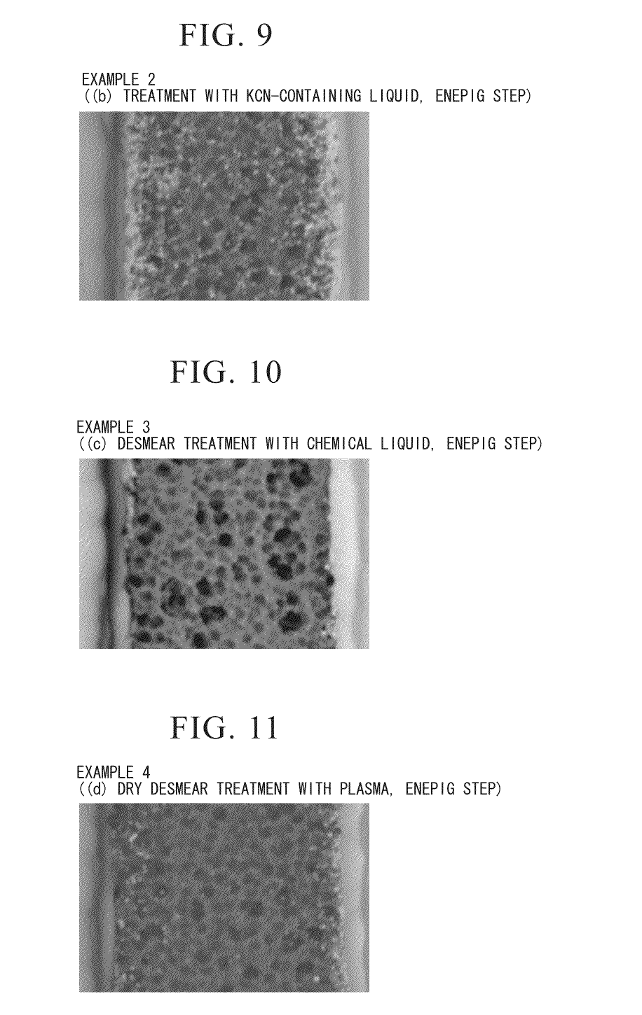

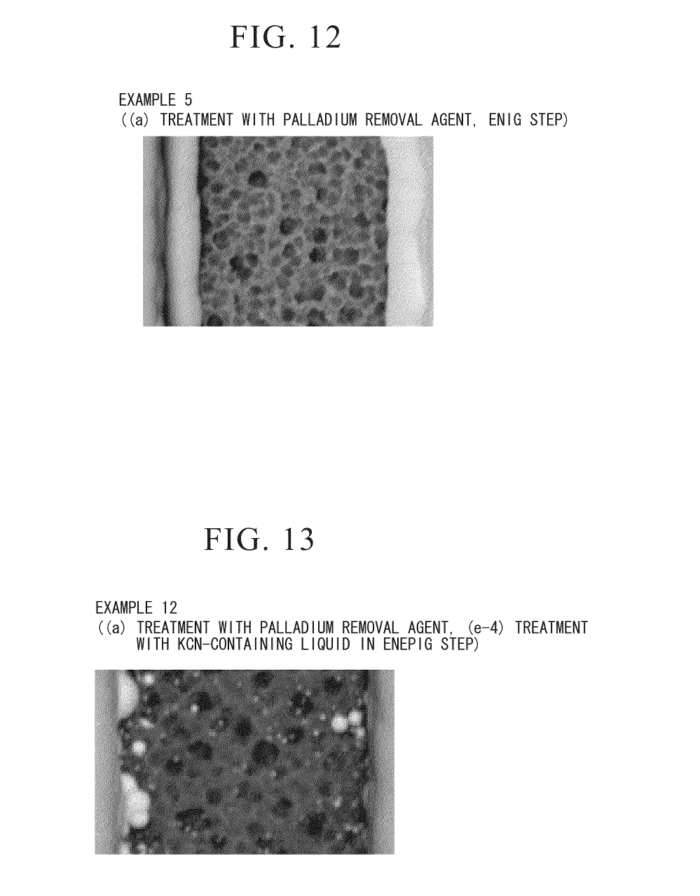

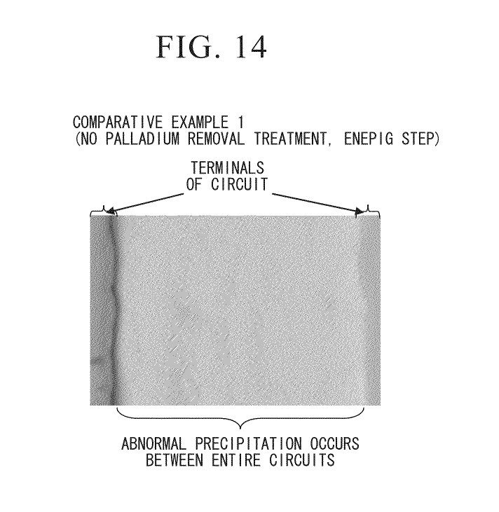

Electron micrographs of Examples 1 to 5 and 12, and Comparative Example 1 are respectively shown in FIG. 8 to FIG. 14. In Examples 1 to 5 and 12 (FIG. 8 to FIG. 13), abnormal precipitation did not occur on a resin surface in the vicinity of a terminal. Although micrographs other than the above micrographs are not attached, it was observed that abnormal precipitation does not generate on a resin surface in the vicinity of a terminal, similar to other Examples. In contrast, Comparative Example 1 (FIG. 14) is an example in the case of no palladium removal treatment, and drastic abnormal precipitation was generated on a resin surface in the vicinity of the terminal (inter-wiring). Although micrographs after ENIG plating of Comparative Example 2 are not attached, severe abnormal precipitation was observed, similar to Comparative Example 1.

### INDUSTRIAL APPLICABILITY

The present inventions can provide a method for manufacturing a base material having a gold-plated metal fine pattern, which is excellent in electroless plating adhesion properties in an SAP process and enables formation of a fine circuit, and also suppresses abnormal precipitation in a gold-plating treatment, thus enabling an improvement in inter-wiring insulation reliability and connection reliability of a fine circuit. According to the above manufacturing method, it is possible to provide a base material having a gold-plated metal fine pattern, particularly a printed wiring board, and a semiconductor device obtained using the printed wiring board.

### REFERENCE SIGNS LIST

1 Core base material
2 Primer resin layer
3 Palladium catalyst
4 Electroless copper plated layer
5 Plating resist
6 Electrolytic copper plated layer
7 Conductor circuit
8 Composite gold-plated layer
9 Metal foil with roughness
9′ Non-roughened metal foil
10 Semiconductor device
11 Motherboard
12 Semiconductor package
13 Interposer
14 Semiconductor device
15 Connection terminal of motherboard
16 (16a, 16b) Solder resist layer of motherboard
17 Core substrate of interposer
18 (18a, 18b, 18c) Conductor circuit layer on side for mounting semiconductor element of interposer
19 (19a, 19b, 19c) Conductor circuit layer on side for connecting motherboard of interposer
(20a, 20b) Connection terminal of interposer
21 (21a, 21b) Solder resist layer of interposer
22 Solder ball
23 Electrode pad of semiconductor element
24 Solder ball
25 Sealing material
30 Semiconductor package
31 Interposer
32 Semiconductor device
33 (33a, 33b) Connection terminal of interposer
34 (34a, 34b) Solder resist layer of interposer
35 Electrode pad of semiconductor element
36 Gold wire
37 Die-bonding material cured layer
38 Solder ball
39 Sealing material

1. A method for manufacturing a base material having a gold-plated metal fine pattern, comprising the steps of:
preparing a base material having a supporting surface made of a resin;
forming a metal fine pattern on the supporting surface made of a resin of the base material by a semi-additive method to obtain a base material having a metal fine pattern; and
applying a gold-plating treatment selected from the group consisting of an electroless nickel-palladium-gold-plating treatment and an electroless nickel-gold-plating treatment to at least one part of a surface of the metal fine pattern; wherein
a primer resin layer having surface roughness represented by the arithmetic average of 0.5 μm or less is formed on the supporting surface made of a resin;
a metal fine pattern is formed on the primer resin layer by a semi-additive method including an electroless metal-plating treatment using a palladium catalyst;
the base material having a metal fine pattern is subjected to at least one palladium removal treatment selected from the group consisting of (a) to (d) shown below, in an optional stage before carrying out the gold-plating treatment after formation of the metal fine pattern:
(a) a treatment with a palladium removal agent,
(b) a treatment with a potassium cyanide (KCN)-containing liquid,
(c) a desmear treatment with a chemical liquid, and
(d) a dry desmear treatment with plasma; and
the palladium removal treatment is carried out, and then the gold-plating treatment is carried out.

2. The method for manufacturing a base material having a gold-plated metal fine pattern according to claim 1, wherein a palladium catalyst is applied on a surface of metal fine pattern of a base material having a metal fine pattern in a gold-plating treatment step after carrying out the palladium removal treatment, and then the base material having a metal fine pattern is subjected to at least one second palladium removal treatment selected from the group consisting of (e) and (f) shown below:
(e) a treatment with a solution at pH 10 to 14, and
(f) a dry desmear treatment with plasma, in an optional stage before an electroless nickel-plating treatment or an electroless palladium-plating treatment is carried out.

3. The method for manufacturing a base material having a gold-plated metal fine pattern according to claim 1, wherein the base material having a metal fine pattern is a printed wiring board, and the metal fine pattern is a conductor circuit on a surface of a printed wiring board.

4. The method for manufacturing a base material having a gold-plated metal fine pattern according to claim 3, wherein the printed wiring board is a motherboard, and line-and-space (L/S) of a conductor circuit at a plating portion is 300 to 500 μm/300 to 500 μm.

5. The method for manufacturing a base material having a gold-plated metal fine pattern according to claim 3, wherein the printed wiring board is an interposer.

6. The method for manufacturing a base material having a gold-plated metal fine pattern according to claim 5, wherein line-and-space (L/S) of a conductor circuit at a plating portion on the side for connecting a semiconductor element of the interposer is 10 to 50 μm/10 to 50 μm.

7. The method for manufacturing a base material having a gold-plated metal fine pattern according to claim 5, wherein line-and-space (L/S) of a conductor circuit at a plating portion on the side for connecting a motherboard of the interposer is 300 to 500 μm/300 to 500 μm.

8. A base material having a gold-plated metal fine pattern, which is manufactured by the method according to claim 1.

9. A printed wiring board in which a composite gold-plated layer selected from the group consisting of a nickel-palladium-gold-plated layer and a nickel-gold-plated layer is formed on a conductor circuit of the printed wiring board surface by the method according to claim 1.

10. The printed wiring board according to claim 9, wherein line-and-space (L/S) of a portion including the composite gold-plated layer of the conductor circuit is 300 to 500 μm/300 to 500 μm.

11. An interposer in which a composite gold-plated layer selected from the group consisting of a nickel-palladium-gold-plated layer and a nickel-gold-plated layer is formed on a conductor circuit of the interposer surface by the method according to claim 1.

12. The interposer according to claim 11, wherein line-and-space (L/S) of a conductor circuit at a plating portion on the side for connecting a semiconductor element of the interposer is 10 to 50 μm/10 to 50 μm.

13. The interposer according to claim 11, wherein line-and-space (L/S) of a conductor circuit at a plating portion on the side for connecting a motherboard of the interposer is 300 to 500 μm/300 to 500 μm.

14. A semiconductor device in which a semiconductor is mounted on the printed wiring board according to claim 9.

15. A semiconductor device in which a semiconductor is mounted on an interposer of a printed wiring board including the interposer according to claim 11.
